(19) United States
(12) Patent Application Publication
(10) Pub. No.: US 2010/0244017 A1
(43) Pub. Date: Sep. 30, 2010

(54) THIN-FILM TRANSISTOR (TFT) WITH AN EXTENDED OXIDE CHANNEL

(76) Inventors: Randy HOFFMAN, Corvallis, OR (US); James W. STASIAK, Lebanon, OR (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/415,980

(22) Filed: Mar. 31, 2009

(51) Int. Cl. H01L 29/786; H01L 21/34

(52) U.S. Cl. 257/43; 438/104; 257/E29.273; 257/E21.46

(57) ABSTRACT

In at least some embodiments, a thin-film transistor (TFT) includes a gate electrode and a gate dielectric adjacent the gate electrode. The TFT also includes a source electrode at least partially aligned with the gate electrode and separated from the gate electrode by the gate dielectric. The TFT also includes a drain electrode laterally offset from the gate electrode by at least 2 μm and separated from the gate electrode by the gate dielectric. The TFT also includes an extended oxide channel between the source electrode and the drain electrode, wherein a portion of the extended oxide channel is ungated.

### BACKGROUND

Semiconductor devices such as thin-film transistors (TFTs) are used in a variety of electronic devices. In part, the performance (e.g., speed) of such electronic devices is a function of the performance and electrical characteristics of such transistors.

### BRIEF DESCRIPTION OF THE DRAWINGS

For a detailed description of exemplary embodiments of the invention, reference will now be made to the accompanying drawings in which:

FIGS. 1A-1F illustrate various semiconductor devices in accordance with embodiments of the disclosure;

FIG. 2 illustrates a cross-sectional schematic of a high-voltage thin-film transistor (HVTFT) in accordance with an embodiment of the disclosure;

FIG. 3 illustrates a method for manufacturing a thin-film transistor in accordance with an embodiment of the disclosure;

FIG. 4 illustrates an active matrix display area in accordance with an embodiment of the disclosure;

FIG. 5 illustrates a micro-electro-mechanical systems (MEMS) device in accordance with an embodiment of the disclosure; and

FIG. 6 illustrates a flexible electronic device in accordance with an embodiment of the disclosure.

### NOTATION AND NOMENCLATURE

Certain terms are used throughout the following description and claims to refer to particular system components. As one skilled in the art will appreciate, technology companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described herein, embodiments of the disclosure are directed to semiconductor devices having an extended oxide channel and to related manufacturing methods. As used herein, an “extended channel” refers to a channel that extends beyond a gate electrode (i.e., the drain electrode is laterally offset from the gate electrode). Thus, the extended oxide channel has a first portion that is gated and a second portion that is ungated. In accordance with at least some embodiments, the second (ungated) portion extends about 2 μm or more beyond the gate electrode. In other words, the drain electrode is laterally offset from the gate electrode by a length (e.g., at least about 2 μm), which is greater than common misalignments in the manufacturing process. The extended oxide channel may comprise zinc oxide (ZnO), tin oxide (SnO₂), indium oxide (In₂O₃), gallium oxide (Ga₂O₃), or combinations thereof such as zinc indium oxide (ZIO), zinc tin oxide (ZTO), indium gallium oxide (IGO), and indium gallium zinc oxide (IGZO).

The disclosed devices and methods were developed as a high-voltage thin-film transistor (HVTFT) technology, including HVTFTs that are at least partially transparent. However, embodiments are not necessarily limited to HVTFTs or transparent applications. Desirable features of the disclosed extended oxide channel technology include high-mobility performance (e.g., approximately 10 cm²/Vs) and low-temperature processing (e.g., less than around 175° Celsius). Disclosed HVTFT embodiments are able to control high voltages (hundreds of volts) at the drain electrode using low voltages (tens of volts) applied at the gate electrode (with the voltage reference being the source electrode) and will enable improved performance and capabilities for semiconductor devices that employ HVTFTs. For example, a desired HVTFT may operate with at least 100 volts applied to the drain material and less than 20 volts applied to the gate material. Examples of semiconductor devices that employ HVTFTs include, for example, micro-electro-mechanical systems (MEMS), active matrix displays, logic circuitry, and amplifiers. Additionally, low-temperature processing as disclosed herein enables the manufacture of HVTFTs on flexible surfaces.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques.

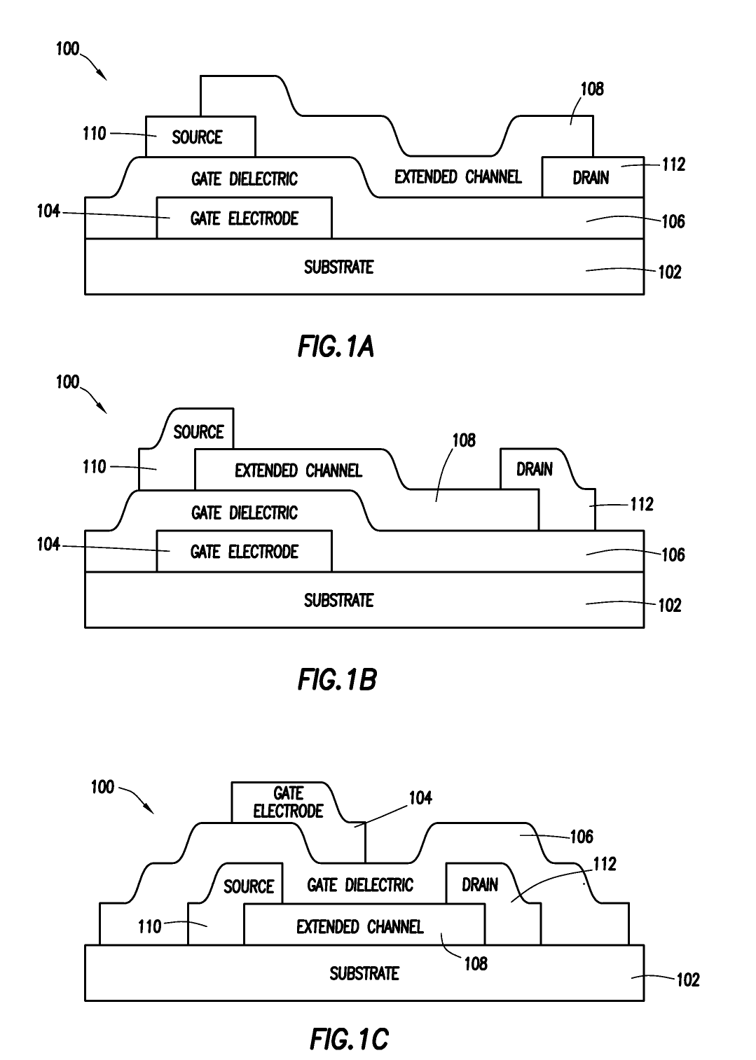

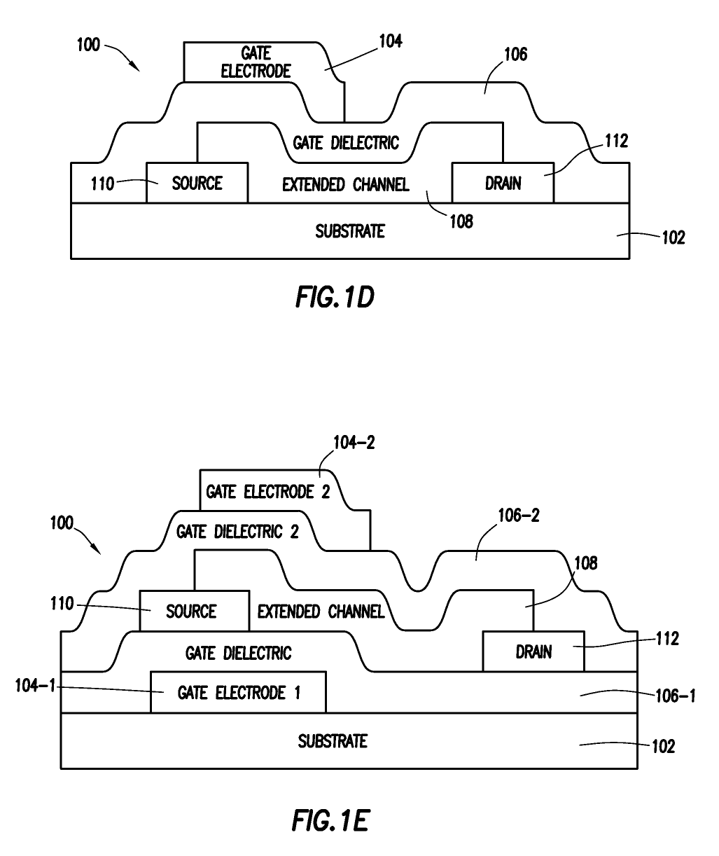

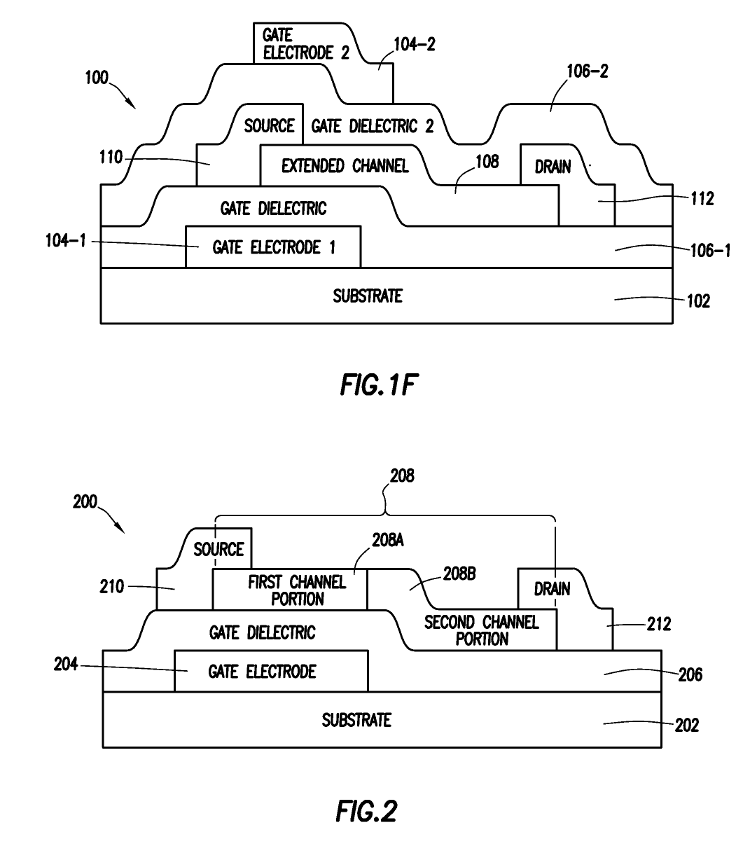

FIGS. 1A-1F illustrate various semiconductor devices in accordance with embodiments of the disclosure. The semiconductor devices represent various thin-film transistor architectures, including but not limited to, top-gate, bottom-gate, coplanar electrode, staggered electrode, single-gate, and double-gate, to name a few. As used herein, a coplanar electrode configuration is intended to mean a transistor structure where the source and drain electrodes are positioned on the same side of the channel as the gate electrode. A staggered electrode configuration is intended to mean a transistor structure where the source and drain electrodes are positioned on the opposite side of the channel as the gate electrode.

FIGS. 1A and 1B illustrate embodiments of bottom-gate transistors, and FIGS. 1C and 1D illustrate embodiments of top-gate transistors. In each of FIGS. 1A-1D, the transistors 100 include a substrate 102, a gate electrode 104, a gate dielectric 106, an extended oxide channel 108, a source electrode 110, and a drain electrode 112. In each of FIGS. 1A-1D, the gate dielectric 106 is positioned between the gate electrode 104 and the source and drain electrodes 110, 112, with the drain electrode 112 being laterally offset from the gate electrode 104. As shown, the gate dielectric 106 physically separates the gate electrode 104 from the source and the drain electrodes 110, 112. Additionally, in each of the FIGS. 1A-1D, the source and the drain electrodes 110, 112 are separately positioned thereby forming a region between the source and drain electrodes 110, 112 for interposing the extended oxide channel 108. Thus, in each of FIGS. 1A-1D, the gate dielectric 106 is positioned adjacent the extended oxide channel 108, and physically separates the source and drain electrodes 110, 112 from the gate electrode 104. Additionally, in each of the FIGS. 1A-1D, the extended oxide channel 108 is positioned adjacent the gate dielectric 106 and is interposed between the source and drain electrodes 110, 112.

In various embodiments, such as in the double-gate embodiments shown in FIGS. 1E and 1F, two gate electrodes 104-1, 104-2 and two gate dielectrics 106-1, 106-2 are illustrated. In such embodiments, the positioning of the gate dielectrics 106-1, 106-2 relative to the extended oxide channel 108 and the source and drain electrodes 110, 112, and the positioning of the gate electrodes 104-1, 104-2 relative to the gate dielectrics 106-1, 106-2 follow the same positioning convention described above where one gate dielectric and one gate electrode are illustrated. That is, the gate dielectrics 106-1, 106-2 are positioned between the gate electrodes 104-1, 104-2 and the source and drain electrodes 110, 112 such that the gate dielectrics 106-1, 106-2 physically separate the gate electrodes 104-1, 104-2 from the source and the drain electrodes 110, 112. As shown, the drain electrode 112 is laterally offset from the gate electrodes 104-1, 104-2.

In each of FIGS. 1A-1F, the extended oxide channel 108 interposed between the source and the drain electrodes 110, 112 provides a controllable electric pathway between the source and drain electrodes 110, 112 such that when a voltage is applied to the gate electrode 104, an electrical charge can move between the source and drain electrodes 110, 112 via the extended oxide channel 108. The voltage applied at the gate electrode 104 can vary the ability of the extended oxide channel 108 to conduct the electrical charge and thus, the electrical properties of the extended oxide channel 108 can be controlled, at least in part, through the application of a voltage at the gate electrode 104. When a high voltage is applied to the drain, a portion of the voltage is dropped laterally across the drain-to-gate offset portion of the channel, thus reducing the voltage (electric field) applied across the gate dielectric and preventing gate dielectric failure (breakdown).

A more detailed description of an embodiment of a HVTFT is illustrated in FIG. 2, which illustrates a cross-sectional schematic of a HVTFT. More specifically, FIG. 2 illustrates a cross-sectional view of an exemplary bottom gate HVTFT 200. It will be appreciated that the different HVTFT layers described in FIG. 2, as well as the materials and methods used are equally applicable to any of the transistor embodiments described herein, including those described in connection with FIGS. 1A-1F.

Moreover, in the various embodiments, the HVTFT 200 can be included in a number of devices including MEMS devices, active matrix display screen devices, logic circuitry, and amplifiers. In various embodiments, HVTFT 200 may be part of a transparent and/or flexible device.

As shown in FIG. 2A, the HVTFT 200 comprises a substrate 202, a gate electrode 204 positioned adjacent the substrate 202, and a gate dielectric 206 positioned adjacent the gate electrode 204. The HVTFT 200 also includes an extended oxide channel 208 contacting the gate dielectric 206, a source electrode 210, and a drain electrode 212. In various embodiments, the extended oxide channel 208 is positioned between and electrically couples the source electrode 210 and the drain electrode 212. As shown in FIG. 2A, the extended oxide channel 208 comprises a first channel portion 208A that is aligned with the gate electrode 204 and a second channel portion 208B that is offset from the gate electrode 204. The length of the second channel portion 208 is selected for compatibility with a maximum drain voltage and may range, for example, between ˜2 μm and 50 μm.

In the embodiment of FIG. 2, the substrate 202 includes glass. Additionally or alternatively, the substrate 202 may include any suitable substrate material or composition for implementing the various embodiments, including flexible substrate materials. Further, the substrate 202 illustrated in FIG. 2 includes an appropriately-patterned layer of Al form the gate electrode 204. However, any number of conductive materials may be used for the gate electrode 204. Such materials may include transparent conductive materials such as an n-type doped In₂O₃, SnO₂, ZnO, or indium-tin oxide (ITO). Other suitable materials include metals such as Mo, Al, Ti, W, Ag, Cu, alloys or multi-layers thereof. Other suitable materials may also include organic conductors and films consisting of carbon nanotubes, nano-particles and/or nano-wires. In the embodiment illustrated in FIG. 2, the thickness of the gate electrode 204 is approximately 200 nm, but may vary depending on the materials used, HVTFT application, and other factors.

The gate dielectric 206 shown in FIG. 2 is blanket coated (unpatterned) in the device area. Although not specifically shown, the gate electrode 204 may be unpatterned or patterned in design (e.g., to form contact vias between the gate electrode layer and overlying conductive layers). In the various embodiments, the gate dielectric 206 can include various layers of different materials having insulating properties representative of gate dielectrics. Such materials can include silicon oxide (SiO2), silicon nitride (SiNx), aluminum oxide (Al₂O₃), hafnium oxide (HfO₂), zirconium oxide (ZrO₂), tantalum pentoxide (Ta₂O₅), various organic dielectric materials, and/or other suitable materials.

The various layers of the transistor structures described herein can be formed using a variety of techniques. For example, the gate dielectric 206 may be deposited by sputter deposition from a sintered HfO₂ ceramic target. Examples of thin-film deposition techniques include, but are not limited to, evaporation (e.g., thermal, e-beam), sputter deposition (e.g., dc reactive sputtering, rf magnetron sputtering, ion beam sputtering), chemical vapor deposition (CVD) including plasma-enhanced CVD (PECVD), atomic layer deposition (ALD), pulsed laser deposition (PLD) and molecular beam epitaxy (MBE). Additionally, alternate methods may also be employed for depositing the various transistor layers of the embodiments of the present disclosure. Such alternate methods can include anodization (electrochemical oxidation) of a metal film, as well as deposition from a liquid precursor such as by spin coating, spray coating, slot coating, or ink-jet printing including thermal and piezoelectric drop-on-demand printing. Film patterning may employ photolithography combined with etching or lift-off processes, or may use alternate techniques such as shadow masking. Chemical and/or electronic doping of one or more of the layers (e.g., the extended oxide channel 208 illustrated in FIG. 2A) may also be accomplished by the introduction of oxygen vacancies and/or substitution of appropriate elements such as Sn, Al, Ge, and Ga.

In the various embodiments, the source electrode 210 and the drain electrode 212 are separately positioned adjacent the gate dielectric 206, and in direct contact with the extended channel layer 208. Although not required, the source and drain electrodes 210, 212 may be formed from the same materials as those discussed with regard to the gate electrode 204. In FIG. 2, the source electrode 210 and the drain electrode 212 have a thickness of about 200 nm. In various embodiments however, the thickness can vary depending on a variety of factors including type of materials, TFT application, or other factors. In various embodiments, the electrodes 210, 212, may include a transparent conductor, such as an n-type doped wide-bandgap semiconductor. Examples include, but are not limited to, n-type doped In₂O₃, SnO₂, indium-tin oxide (ITO), or ZnO. The electrodes 210, 212 may also include metals such as Al, Mo, Ti, Ag, Cu, Au, Pt, W, or Ni, and alloys or multi-layers thereof. Other suitable materials may also include organic conductors and films consisting of carbon nanotubes, nano-particles and/or nano-wires. In the various embodiments of the present disclosure, all of the electrodes 204, 210, and 212 may include transparent materials such that the various embodiments of the transistors may be substantially transparent.

In accordance with various embodiments, the extended oxide channel 208 comprises zinc oxide (ZnO), tin oxide (SnO₂), indium oxide (In₂O₃), gallium oxide (Ga₂O₃), or combinations thereof, including zinc indium oxide (ZIO), zinc tin oxide (ZTO), indium gallium oxide (IGO), and indium gallium zinc oxide (IGZO). The materials used for the extended oxide channel 208 may correspond to amorphous films, although crystalline or mixed-phase structures are possible as well. For example, a zinc tin oxide composition may comprise an amorphous film characterized by particular composition (e.g., a particular zinc to tin ratio) but without a well-defined structural order associated with a particular crystalline phase or structure. Alternately, a zinc tin oxide composition may comprise a single-phase crystalline (including poly-crystalline) structure such as Zn2SnO4; a mixed-phase crystalline (including poly-crystalline) structure of segregated ZnO and SnO2 regions; or a mixed-phase structure of segregated crystalline regions (such as ZnO, SnO2, or Zn2SnO4) and amorphous regions (characterized by composition but not by a crystalline phase or structure).

In at least some embodiments, the source, drain, and gate electrodes may include a substantially transparent material. By using substantially transparent materials for the source, drain, and gate electrodes, areas of the thin-film transistor can be transparent to the portion of the electromagnetic spectrum that is visible to the human eye. In the transistor arts, a person of ordinary skill will appreciate that devices such as active matrix liquid crystal displays having display elements (pixels) coupled to TFTs having substantially transparent materials for selecting or addressing the pixel to be on or off may benefit display performance by allowing more light to be transmitted through the display.

In the embodiment of FIG. 2, the extended oxide channel 208 is positioned adjacent the gate dielectric 206 and between the source and drain electrodes 210, 212, so as to contact and provide direct electrical contact to the electrodes 210 and 212. An applied voltage at the gate electrode 204 can facilitate electron accumulation in the extended oxide channel 208. In this manner, the extended oxide channel 208 can allow for on/off operation by controlling current flowing between the drain electrode 212 and the source electrode 210 using a voltage applied to the gate electrode 204.

The use of the extended oxide channel 208 illustrated in the embodiments of the present disclosure is beneficial for a wide variety of thin-film applications in integrated circuit structures. For example, such applications include transistors, as discussed herein, such as thin-film transistors, top-gate, bottom-gate, coplanar electrode, staggered electrode, single-gate, and double-gate, to name only a few. In the various embodiments, transistors (e.g., TFTs) of the present disclosure can be provided as switches or amplifiers, where applied voltages to the gate electrodes of the transistors can affect a flow of electrons through the extended oxide channel 208. As one of ordinary skill will appreciate, when the transistor is used as a switch, the transistor can operate in the saturation region, and where the transistor is used as an amplifier, the transistor can operate in the linear region. In addition, transistors incorporating the extended oxide channel 208 may be incorporated into integrated circuits and structures such as visual display panels (e.g., active matrix LCD displays) as is shown and described in connection with FIG. 4 below. In display applications and other applications, it may be desirable to fabricate one or more of the components of the HVTFT 200 to be at least partially transparent. Further, it may be desirable to fabricate one or more of the components of the HVTFT 200 on a flexible or curved substrate.

Embodiments of the present disclosure also include methods of forming metallic films on a surface of a substrate or substrate assembly, such as a glass substrate, with or without layers or structures formed thereon, to form integrated circuits, and in particular HVTFTs as described herein. It is to be understood that methods of the present disclosure are not limited to deposition on glass substrates. For example, other substrate types such as flexible substrates including organics (“plastics”), metal foils, or combinations thereof may be used as well. Furthermore, the methods disclosed herein may be applied to non-wafer substrates such as fibers or wires. In general, the films can be formed directly on the lowest surface of the substrate, or they can be formed on any of a variety of the layers (surfaces) as in a patterned wafer, for example.

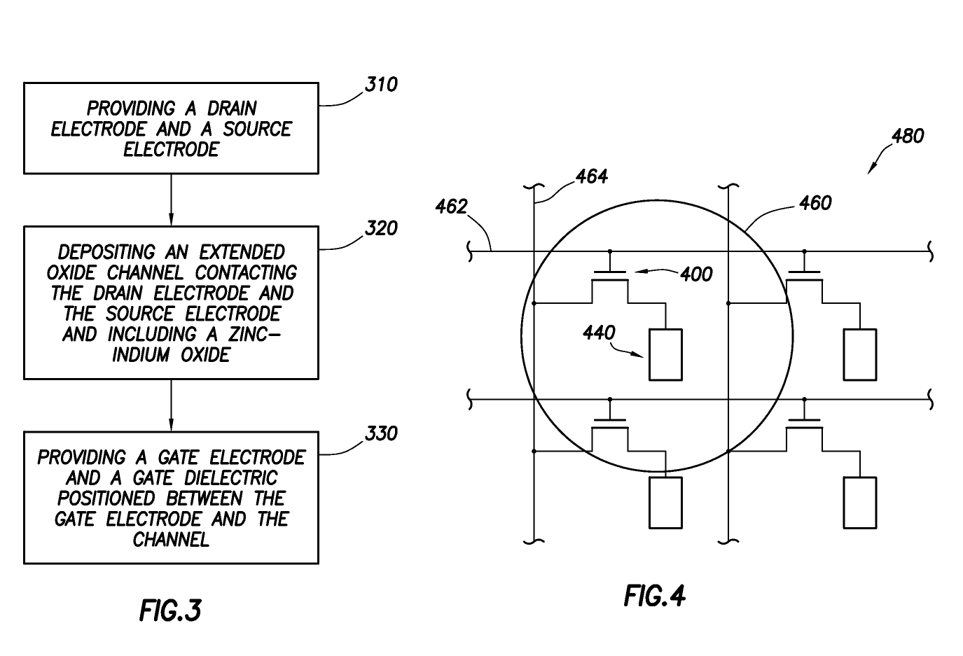

FIG. 3 illustrates a method for manufacturing a thin-film transistor in accordance with an embodiment of the disclosure. In block 310, a drain electrode and a source electrode can both be provided. For example, both the drain electrode and the source electrode can be provided on the substrate of a substrate assembly. As used herein, the term “substrate” refers to the base substrate material layer, e.g., the surface of a glass substrate. Meanwhile, the term “substrate assembly” refers to a substrate having one or more layers or structures formed thereon. Examples of substrate types include, but are not limited to, glass, plastic, and metal, and include such physical forms as sheets, films, and coatings. In various embodiments, substrates may be opaque or substantially transparent. In accordance with at least some embodiments, transparency is quantified by % optical transmission in the visible spectrum (about 400 nm to about 700 nm) and embodiments have at least 50% transmission. Further, in various embodiments, substrates may be rigid or flexible. For example, flexible substrates may be elastically deformative yet resilient as understood by those of skill in the art. Further, in various embodiments, substrates may be flat or curved. In accordance with at least some embodiments, curvature is quantified by radius of curvature and embodiments have less than 1 m radius of curvature.

In block 320, an extended oxide channel contacting the drain electrode and the source electrode is deposited. For example, the extended oxide channel can be deposited between the drain electrode and the source electrode so as to electrically couple the two electrodes. At block 330, a gate electrode and a gate dielectric are provided, with the gate dielectric positioned between the gate electrode and the extended oxide channel. In accordance with embodiments, only part of the extended oxide channel is gated and the drain electrode is laterally offset from the gate electrode.

In accordance with at least some embodiments, depositing the extended oxide channel layer (as in block 320) may include providing a precursor composition including one or more precursor compounds. Various combinations of the precursor compounds described herein can be used in the precursor composition. Thus, as used herein, a “precursor composition” refers to a solid or liquid that includes one or more precursor compounds of the formulas described herein optionally mixed with one or more compounds of formulas other than those described herein. As used herein, “liquid” refers to a solution or a neat liquid (a liquid at room temperature or a solid at room temperature that melts at an elevated temperature). As used herein, a “solution” does not call for complete solubility of the solid; rather, the solution may have some undissolved material. More desirably, however, there is a sufficient amount of the material that can be carried by the organic solvent into the vapor phase for chemical vapor deposition processing. The precursor compounds can also include one or more organic solvents suitable for use in a chemical vapor deposition system, as well as other additives, such as free ligands, that assist in the vaporization of the desired compounds.

Although not required, the extended oxide channel layer may have a uniform composition of zinc oxide (ZnO), tin oxide (SnO₂), indium oxide (In₂O₃), gallium oxide (Ga₂O₃), or combinations thereof, throughout its thickness. Alternatively, the concentrations of materials in the extended oxide channel may vary as the layer is formed. As will be appreciated, the thickness of the extended oxide channel layer will be dependent upon the application for which it is used. For example, the thickness for the extended oxide channel layer may have a range of about 5 nanometer to about 300 nanometers.

The embodiments described herein may be used for fabricating chips, integrated circuits, monolithic devices, semiconductor devices, MEMS, and microelectronic devices such as display devices. For example, FIG. 4 illustrates an embodiment in which HVTFTs are implemented in an active-matrix liquid-crystal display (AMLCD) 480. In FIG. 4, the AMLCD 480 can include pixel components (i.e., liquid crystal elements) 440 in a matrix of a display area 460. The pixel components 440 in the matrix can be coupled to HVTFTs 400 also located in the display area 460. The HVTFTs 400 can include embodiments of HVTFTs with an extended oxide channel as disclosed herein. Additionally, the AMLCD 480 can include orthogonal control lines 462 and 464 for supplying an addressable signal voltage to the HVTFTs 400 to influence the HVTFTs 400 to turn on and off and to thereby selectively provide power the pixel components 440 (e.g., to provide an image on the AMLCD 480).

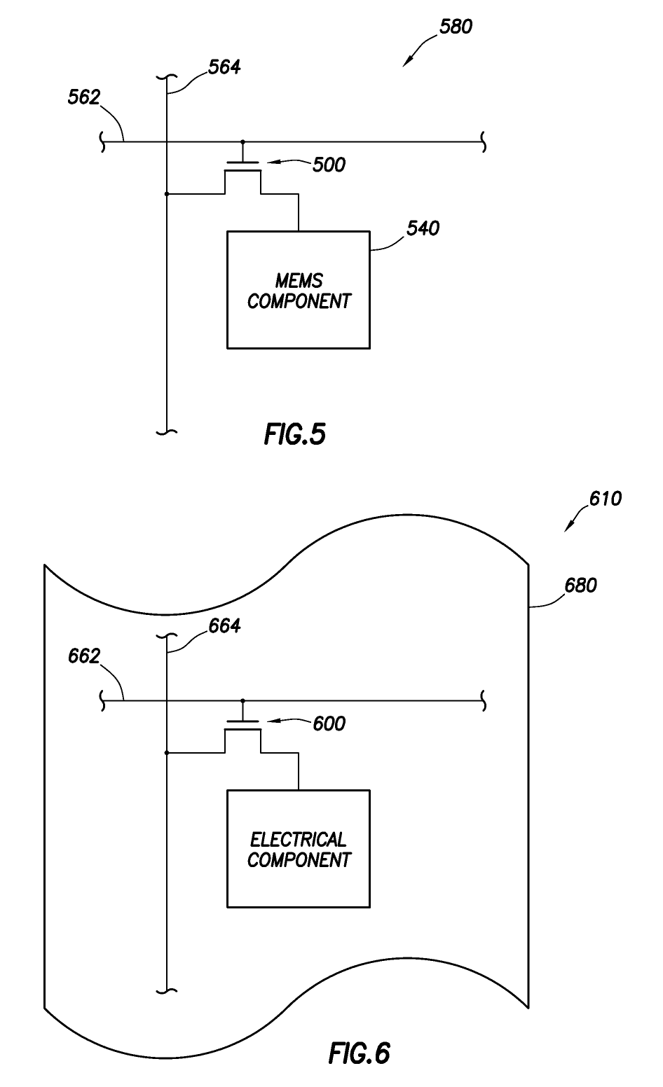

As another example, FIG. 5 illustrates an embodiment in which HVTFTs are implemented in a MEMS device 580. In FIG. 5, the MEMS device 580 comprises an HVTFT 500 coupled to a MEMS component 540. Examples of the MEMS component 540 include, but are not limited to, accelerometers, gyroscopes, optical and RF switches, actuators, transducers, pressure sensors, biosensors, or chemical sensors. In FIG. 5, the HVTFT 500 has an extended oxide channel as disclosed herein. Additionally, the MEMS device 580 can include control lines 562 and 564 to influence the HVTFT 500 to turn on and off and to thereby selectively provide power to the MEMS component 540.

As another example, FIG. 6 illustrates an embodiment in which HVTFTs are implemented in a flexible electronic device 610. In FIG. 6, the flexible electronic device 610 comprises a flexible base or substrate 680 having a HVTFT 600 and an electrical component 640 formed thereon using low-temperature processes. The flexible base 680 may be, for example, a transparent plastic material, although other elastically deformative materials are possible as well. Examples of the electrical component 640 include, but are not limited to the pixel component 440, the MEM component 540, or other components. In FIG. 6, the HVTFT 600 has an extended oxide channel as disclosed herein. Additionally, the flexible electronic device 610 can include control lines 662 and 664 to influence the HVTFT 600 to turn on and off and to thereby selectively provide power to the electronic component 640.

Although specific exemplary embodiments have been illustrated and described herein, those of ordinary skill in the art will appreciate that an arrangement calculated to achieve the same techniques can be substituted for the specific exemplary embodiments shown. This disclosure is intended to cover adaptations or variations of the embodiments of the invention. It is to be understood that the above description has been made in an illustrative fashion, and not a restrictive one.

In the foregoing Detailed Description, various features are grouped together in a single exemplary embodiment for the purpose of streamlining the disclosure. This method of disclosure is not to be interpreted as reflecting an intention that the embodiments of the invention necessitate more features than are expressly recited in each claim. Rather, as the following claims reflect, inventive subject matter lies in less than all features of a single disclosed exemplary embodiment. Thus, the following claims are hereby incorporated into the Detailed Description, with each claim standing on its own as a separate embodiment.

What is claimed is:

1. A thin-film transistor (TFT), comprising:
a gate electrode;
a gate dielectric adjacent the gate electrode;
a source electrode at least partially aligned with the gate electrode and separated from the gate electrode by the gate dielectric;
a drain electrode laterally offset from the gate electrode by at least about 2 μm and separated from the gate electrode by the gate dielectric; and
an extended oxide channel between the source electrode and the drain electrode, wherein a portion of said extended oxide channel is ungated.

2. The TFT of claim 1 wherein the extended oxide channel comprises a combination of at least two materials selected from a list consisting of zinc oxide, tin oxide, indium oxide, and gallium oxide.

3. The TFT of claim 2 wherein the extended oxide channel comprises an amorphous material.

4. The TFT of claim 1 wherein the extended oxide channel comprises at least one material selected from a list consisting of zinc indium oxide, zinc tin oxide, indium gallium oxide, and indium gallium zinc oxide.

5. The TFT of claim 1 wherein the gate electrode, the source electrode and the drain electrode are coplanar.

6. The TFT of claim 1 wherein the gate electrode, the source electrode and the drain electrode are staggered.

7. The TFT of claim 1 wherein the TFT is a top-gate transistor.

8. The TFT of claim 1 wherein the TFT is a bottom-gate transistor.

9. A method, comprising:
constructing a thin-film transistor (TFT) by
depositing a gate electrode;
depositing a gate dielectric adjacent the gate electrode;
depositing an oxide channel adjacent the gate dielectric and across from the gate electrode, wherein the oxide channel extends beyond an edge of the gate electrode; and
depositing a source electrode and a drain electrode in contact with the oxide channel, the drain electrode being laterally offset from the gate electrode by at least about 2 μm.

10. The method of claim 9 further comprising selecting the oxide channel as a combination of at least two materials selected from a list consisting of zinc oxide, tin oxide, indium oxide, and gallium oxide.

11. The method of claim 9 wherein constructing the TFT further comprises depositing said gate electrode, said gate dielectric, said oxide channel, said source electrode, and said drain electrode over a curved substrate.

12. The method of claim 9 wherein constructing the TFT further comprises depositing said gate material, said gate dielectric material, said oxide channel material, said source material, and said drain material over a flexible substrate.

13. The method of claim 9 further comprising operating the TFT by applying at least 100 volts to the drain material and less than 20 volts to the gate material.

14. The method of claim 9 further comprising interfacing the TFT with a Micro-Electro-Mechanical System (MEMS) component.

15. An electronic device, comprising:
a thin-film transistor (TFT), the TFT having a multi-component oxide channel with a gated portion and an ungated portion, wherein the ungated portion is at least about 2 μm in length; and
a component coupled to the TFT, wherein the component selectively receives power from the TFT.

16. The electronic device of claim 15 wherein the multi-component oxide channel comprises a combination of at least two materials selected from a list consisting of zinc oxide, tin oxide, indium oxide, and gallium oxide.

17. The electronic device of claim 15 wherein the component comprises an active-matrix display component.

18. The electronic device of claim 15 wherein the component comprises a Micro-Electro-Mechanical System (MEMS) component.

19. The electronic device of claim 15 wherein the TFT and the electronic device are at least partially transparent.

20. The electronic device of claim 15 wherein the electronic device is elastically deformative.
